(19) United States
(12) Patent Application Publication
(10) Pub. No.: US 2023/0169255 A1
(43) Pub. Date: Jun. 1, 2023

(54) Methods And Systems For Data Driven Parameterization And Measurement Of Semiconductor Structures

(71) Applicant: KLA Corporation, Milpitas, CA (US)

(72) Inventors: Stilian Ivanov Pandev, Santa Clara, CA (US); Arvind Jayaraman, Windsor (CA); Proteek Chandan Roy, Ann Arbor, MI (US); Hyowon Park, Milpitas, CA (US); Antonio Arion Gellineau, Santa Clara, CA (US); Sungchol Yoo, San Jose, CA (US)

(21) Appl. No.: 17/993,565

(22) Filed: Nov. 23, 2022

Related U.S. Application Data
(60) Provisional application No. 63/284,645, filed on Dec. 1, 2021.

(51) Int. Cl. G06F 30/398

(52) U.S. Cl. CPC G06F 30/398

(57) ABSTRACT

Methods and systems for generating optimized geometric models of semiconductor structures parameterized by a set of variables in a latent mathematical space are presented herein. Reference shape profiles characterize the shape of a semiconductor structure of interest over a process space. A set of observable geometric variables describing the reference shape profiles is transformed to a set of latent variables. The number of latent variables is smaller than the number of observable geometric variables, thus the dimension of the parameter space employed to characterize the structure of interest is reduced. This dramatically reduces the mathematical dimension of the measurement problem to be solved. As a result, measurement model solutions involving regression are more robust, and training of machine learning based measurement models is simplified. Geometric models parameterized by a set of latent variables are useful for generating measurement models for optical metrology, x-ray metrology, and electron beam based metrology.

### CROSS REFERENCE TO RELATED APPLICATION

The present application for patent claims priority under 35 U.S.C. § 119 from U.S. provisional patent application Ser. No. 63/284,645, entitled “Method for Data Driven Parameterization and Measurement,” filed Dec. 1, 2021, the subject matter of which is incorporated herein by reference in its entirety.

### TECHNICAL FIELD

The described embodiments relate to metrology systems and methods, and more particularly to methods and systems for improved measurement accuracy.

### BACKGROUND INFORMATION

Semiconductor devices such as logic and memory devices are typically fabricated by a sequence of processing steps applied to a specimen. The various features and multiple structural levels of the semiconductor devices are formed by these processing steps. For example, lithography among others is one semiconductor fabrication process that involves generating a pattern on a semiconductor wafer. Additional examples of semiconductor fabrication processes include, but are not limited to, chemical-mechanical polishing, etch, deposition, and ion implantation. Multiple semiconductor devices may be fabricated on a single semiconductor wafer and then separated into individual semiconductor devices.

Metrology processes are used at various steps during a semiconductor manufacturing process to detect defects on wafers to promote higher yield. Optical, electron beam, and x-ray based metrology techniques offer the potential for high throughput without the risk of sample destruction. A number of techniques including scatterometry and reflectometry implementations and associated analysis algorithms are commonly used to characterize critical dimensions, film thicknesses, composition and other parameters of nanoscale structures.

As devices (e.g., logic and memory devices) move toward smaller nanometer-scale dimensions, characterization becomes more difficult. Devices incorporating complex three-dimensional geometry and materials with diverse physical properties contribute to characterization difficulty. Device shapes and profiles are changing dramatically. In one example, recently conceived semiconductor devices incorporate new complex three-dimensional geometry and materials with diverse orientation and physical properties that are particularly difficult to characterize, particularly with optical metrology.

In response to these challenges, more complex metrology tools have been developed. Measurements are performed over large ranges of several machine parameters (e.g., wavelength, azimuth and angle of incidence, etc.), and often simultaneously. As a result, the measurement time, computation time, and the overall time to generate reliable results, including measurement recipes and accurate measurement models, increases significantly.

Existing model based metrology methods typically include a series of steps to model and then measure structure parameters. Typically, measurement data (e.g., DOE spectra) is collected from a set of samples or wafers, a particular metrology target, a testing critical dimension target, an in-cell actual device target, an SRAM memory target, etc. An accurate model of the optical response from these complex structures includes a model of the geometric features, dispersion parameter, and the measurement system is formulated. Typically, a regression is performed to refine the geometric model. In addition, simulation approximations (e.g., slabbing, Rigorous Coupled Wave Analysis (RCWA), etc.) are performed to avoid introducing excessively large errors. Discretization and RCWA parameters are defined. A series of simulations, analysis, and regressions are performed to refine the geometric model and determine which model parameters to float. A library of synthetic spectra is generated. Finally, measurements are performed using the library or regression in real time with the geometric model.

Geometric models of device structures being measured are typically parameterized using generic families of functions that characterize any shape with arbitrary accuracy or employing a parameterization defined by a user based on a specific understanding of the expected model changes.

In some examples, geometric models of device structures being measured are assembled from primitive structural building blocks by a user of a measurement modeling tool. These primitive structural building blocks are simple geometric shapes (e.g., square frusta) that are assembled together to approximate more complex structures. The primitive structural building blocks are sized by the user and sometimes customized based on user input to specify the shape details of each primitive structural building block. In one example, each primitive structural building block includes an integrated customization control panel where users input specific parameters that determine the shape details to match an actual, physical structure being modeled. Similarly, primitive structural building blocks are joined together by constraints that are also manually entered by the user. For example, the user enters a constraint that ties a vertex of one primitive building block to a vertex of another building block. This allows the user to build models that represent a series of the actual device geometries when the size of one building block changes. User-defined constraints between primitive structural building blocks enable broad modeling flexibility. For example, the thicknesses or heights of different primitive structural building blocks can be constrained to a single parameter in multi-target measurement applications. Furthermore, primitive structural building blocks have simple geometric parameterizations which the user can constrain to application-specific parameters. For example, the sidewall angle of a resist line can be manually constrained to parameters representing the focus and dose of a lithography process.

Although models constructed from primitive structural building blocks offer a wide range of modeling flexibility and user control, the model building process becomes very complex and error prone when modeling complex semiconductor structures.

In many examples, the number of parameters required to describe a complex shape is relatively large. This increases the mathematical dimension of the measurement problem to be solved. As a result, measurement model solutions involving regression often suffer from multiple minima, and machine learning based measurement models are often difficult to train due to high parameter correlation and low sensitivity.

In summary, modelling of complex semiconductor structures with existing geometric modelling tools requires the specification of a large number of structural primitives, constraints, and independent parameters that give rise to computational problems and introduce limitations on achievable accuracy. As complex semiconductor structures become more common, improved modeling methods and tools are desired.

### SUMMARY

Methods and systems for generating optimized geometric models of semiconductor structures parameterized by a set of variables in a latent mathematical space are presented herein. Parameterizing a structure under measurement by a set of latent variables, rather than observable, geometric variables, significantly reduces the number of parameters required to describe a complex shape. This dramatically reduces the mathematical dimension of the measurement problem to be solved. As a result, measurement model solutions involving regression are more robust, and training of machine learning based measurement models is simplified. Geometric models parameterized by a set of latent variables of semiconductor structures are useful for generating measurement models for optical metrology, x-ray metrology, and electron beam based metrology.

Reference shape profiles characterize the shape of a semiconductor structure of interest. The reference shape profiles are parameterized by a set of observable geometric variables, e.g., critical dimensions, height, ellipticity, tilt, etc.

In one aspect, the set of observable geometric variables are transformed to a set of latent variables. The set of latent variables characterizing the reference shape profiles define the geometry of the structure of interest in an alternative mathematical space. Changes in values of the latent variables represent changes in the geometry of the structure of interest. The number of latent variables is smaller than the number of observable geometric variables, thus the dimension of the parameter space employed to characterize the structure of interest is reduced.

In some examples, the transformation of the set of observable geometric variables to the set of latent variables involves a principal component analysis (PCA), a weighted PCA, or a trained autoencoder. In some examples, the transformation of the set of observable geometric variables to the set of latent variables involves a hybrid parameterization including a latent space parameterization as described hereinbefore and a function fit to differences between the reference shape profiles and reconstructed profiles derived from values of the latent variables. The summation of the latent space parameterization and functional fit provides a more accurate representation of the reference shape profiles with a relatively small number of independent variables.

In general, any process driven parameterization or combination of different parameterizations may be employed to reduce the dimension of the parameter space employed to characterize the structure of interest.

In another further aspect, a set of reconstructed shape profiles is determined based on a sampling of values of the set of latent variables. In one example, reconstructed shape profiles are generated by randomly sampling from the range of the latent variables. For purposes of comparison, the sampled values of the latent variables are transformed back to values of the observable geometric variables by inverse transformation from the latent space to the observable geometric space.

In another further aspect, the set of latent variables is truncated to a reduced set of latent variables based on differences between the first set of reconstructed shape profiles and the reference shape profiles. The difference between profiles reconstructed from sampled values of the latent variables and the reference shape profiles provides a quantifiable measure of the accuracy of the representation of the reference shape profiles in the latent mathematical space.

In another further aspect, a set of reconstructed shape profiles is generated based on a sampling of values of the latent variables, and in addition, a mathematical function is fit to differences between the reference shape profiles and the reconstructed shape profiles. Another set of reconstructed shape profiles is subsequently generated based on a sum of the reconstructed shape profiles derived from values of the latent variables and the fitted curve. The resulting reconstructed shape profiles can be employed to train a measurement model.

In another further aspect, the range of values of one or more of the set of observable geometric variables is extended to effectively expand the range of training set of reference shape profiles. The extended training set of reference shape profiles is then employed as the basis for generating the transformation to latent space, e.g., by PCA, trained autoencoder, etc.

In another further aspect, non-physical shape profiles are eliminated from reconstructed shape profiles generated from the set of latent variables before the reconstructed profile data set is employed to train a measurement model.

In another further aspect, a measurement model is trained based at least in part on the reconstructed shape profiles derived from the optimized geometric model of the structure under measurement. A large number of reconstructed shape profiles spanning the relevant process variations are efficiently generated based on the optimized geometric model. A measurement simulation tool is employed to generate synthetic measurement data, e.g., spectra, images, electron density maps, etc., associated with each different reconstructed shape profile. The reconstructed shape profiles and corresponding sets of measurement data comprise a training data set employed to train a measurement model.

In another further aspect, a model building tool employs a trained measurement model to estimate values of observable geometric parameters of interest associated with a structure under measurement.

The foregoing is a summary and thus contains, by necessity, simplifications, generalizations and omissions of detail; consequently, those skilled in the art will appreciate that the summary is illustrative only and is not limiting in any way. Other aspects, inventive features, and advantages of the devices and/or processes described herein will become apparent in the non-limiting detailed description set forth herein.

### BRIEF DESCRIPTION OF THE DRAWINGS

FIG. 1 is a diagram illustrative of an embodiment of a system 100 in one embodiment for measuring characteristics of a semiconductor wafer based on optimized geometric models of the semiconductor structures under measurement as described herein.

FIG. 2 is a diagram illustrative of an embodiment of a model building and analysis engine 130 configured to generate optimized geometric models of the semiconductor structures under measurement as described herein.

FIG. 3 is a plot illustrative of a number of user generated reference shape profiles associated with a semiconductor structure of interest.

FIG. 4 is a plot illustrative of a number of reference shape profiles and reconstructed shape profiles generated by an optimized geometric model of a semiconductor structure of interest.

FIG. 5 is a plot illustrative of a root mean squared error measure of the differences between values of a critical dimension (CD-RMSE) associated with a set of reference shape profiles and the corresponding values of the critical dimension associated with reconstructed profiles predicted by an optimized geometric model.

FIG. 6 is a plot illustrative of a root mean squared error measure of the differences between values of a critical dimension (CD-RMSE) associated with a set of reference shape profiles and the corresponding values of the critical dimension associated with reconstructed profiles predicted by an optimized geometric model at different heights.

FIG. 7 is a plot illustrative of a number of reference shape profiles and a number of reconstructed shape profiles generated by an optimized geometric model that capture different etch depths.

FIGS. 8A-C depict both reference shape profiles and reconstructed profiles associated with the shallow, middle, and deep etch structures, respectively. The reconstructed profiles are generated by an optimized geometric model defined by latent variables generated by a principal component analysis.

FIGS. 9A-C depict both reference shape profiles and reconstructed profiles associated with the shallow, middle, and deep etch structures depicted in FIG. 7. The reconstructed profiles are generated by an optimized geometric model defined by latent variables generated by a weighted principal component analysis.

FIG. 10 is a plot illustrative of an extended training set of reference shape profiles including a number of reference shape profiles extended by scaling the reference profile height values by 20%.

FIG. 11 is a plot illustrative of an extended training set of reference shape profiles including a number of reference shape profiles extended by shifting the range of critical dimensions by 20%.

FIG. 12 is a plot illustrative of an extended training set of reference shape profiles including a number of reference shape profiles extended by scaling the range of critical dimensions by 20%.

FIG. 13 is a diagram illustrative of system 300 in another embodiment for measuring characteristics of a semiconductor wafer based on optimized geometric models of the semiconductor structures under measurement as described herein.

FIG. 14 is a diagram illustrative of an embodiment of a model building and analysis engine 350 configured to generate optimized geometric models of the semiconductor structures under measurement as described herein.

FIG. 15 is a diagram illustrative of a system 500 in another embodiment for measuring characteristics of a semiconductor wafer based on optimized geometric models of the semiconductor structures under measurement as described herein.

FIG. 16 illustrates a method 200 for training a measurement model for measuring characteristics of a semiconductor wafer based on optimized geometric models of the semiconductor structures under measurement as described herein.

### DETAILED DESCRIPTION

Reference will now be made in detail to background examples and some embodiments of the invention, examples of which are illustrated in the accompanying drawings.

Methods and systems for generating optimized geometric models of semiconductor structures parameterized by a set of variables in a latent mathematical space are presented herein. Measurements of critical dimensions (CDs), thin film thickness, optical properties and compositions, overlay, lithography focus/dose, etc., typically require a geometric model of the structure of interest. Parameterizing a structure under measurement by a set of latent variables, rather than observable, geometric variables, significantly reduces the number of parameters required to describe a complex shape. This dramatically reduces the mathematical dimension of the measurement problem to be solved. As a result, measurement model solutions involving regression are more robust, and training of machine learning based measurement models is simplified.

Optimization of a geometric model is based on the expected geometry of the structures under measurement. The expected geometry is informed by process data, user expectations of shape geometry, process simulation data, or any combination thereof. An optimized parameterization of the geometric model narrowly defines the parameter space of possible shape profiles and effectively constrains the geometric model.

In some examples, metrology systems employ geometric models parameterized by a set of latent variables to measure structural and material characteristics (e.g., material composition, dimensional characteristics of structures and films, etc.) associated with semiconductor fabrication processes. Geometric models parameterized by a set of latent variables of semiconductor structures enable measurement model generation that is substantially simpler, less error prone, and more accurate. As a result, time to useful measurement results is significantly reduced, particularly when modelling complex structures. Geometric models parameterized by a set of latent variables of semiconductor structures are useful for generating measurement models for optical metrology, x-ray metrology, and electron beam based metrology.

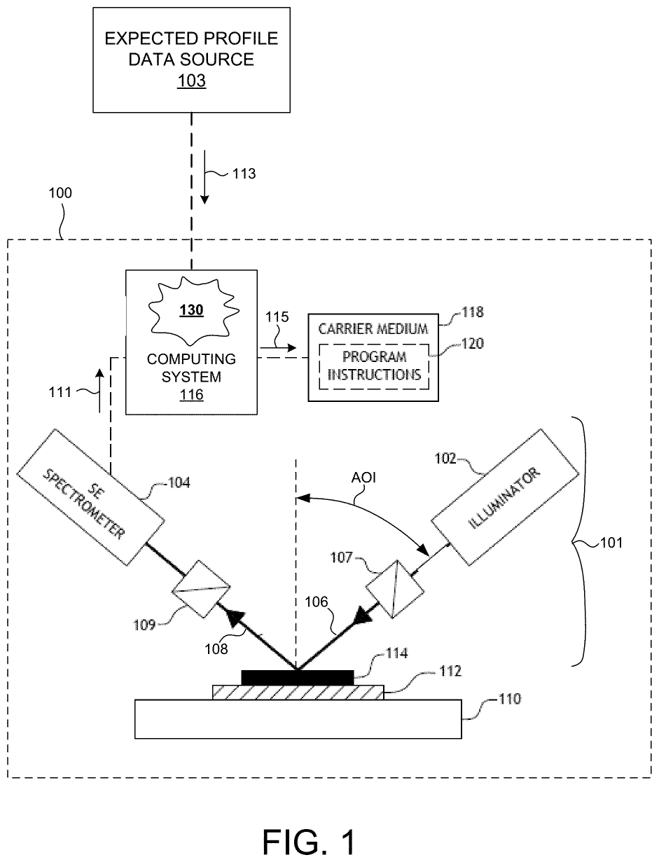

FIG. 1 illustrates a system 100 for measuring characteristics of a semiconductor wafer. As shown in FIG. 1, system 100 may be used to perform spectroscopic ellipsometry measurements of one or more structures 114 of a semiconductor wafer 112 disposed on a wafer positioning system 110. In this aspect, the system 100 may include a spectroscopic ellipsometer equipped with an illuminator 102 and a spectrometer 104. The illuminator 102 of the system 100 is configured to generate and direct illumination of a selected wavelength range (e.g., 150-4500 nm) to the structure 114 disposed on the surface of the semiconductor wafer 112. In turn, the spectrometer 104 is configured to receive light from the surface of the semiconductor wafer 112. It is further noted that the light emerging from the illuminator 102 is polarized using a polarization state generator 107 to produce a polarized illumination beam 106. The radiation reflected by the structure 114 disposed on the wafer 112 is passed through a polarization state analyzer 109 and to the spectrometer 104. The radiation received by a detector of spectrometer 104 in the collection beam 108 is analyzed with regard to polarization state, allowing for spectral analysis of radiation passed by the analyzer. These spectra 111 are passed to the computing system 116 for analysis of the structure 114.

In a further embodiment, the metrology system 100 is a measurement system 100 that includes one or more computing systems 116 configured to execute model building and analysis tool 130 in accordance with the description provided herein. In the preferred embodiment, model building and analysis tool 130 is a set of program instructions 120 stored on a carrier medium 118. The program instructions 120 stored on the carrier medium 118 are read and executed by computing system 116 to realize model building and analysis functionality as described herein. The one or more computing systems 116 may be communicatively coupled to the spectrometer 104. In one aspect, the one or more computing systems 116 are configured to receive measurement data 111 associated with a measurement (e.g., critical dimension, film thickness, composition, process, etc.) of the structure 114 of specimen 112. In one example, the measurement data 111 includes an indication of the measured spectral response (e.g., measured intensity as a function of wavelength) of the specimen by measurement system 100 based on the one or more sampling processes from the spectrometer 104. In some embodiments, the one or more computing systems 116 are further configured to determine specimen parameter values of structure 114 from measurement data 111.

In some examples, metrology based on optical scatterometry involves determining the dimensions of the sample by the inverse solution of a pre-determined measurement model with the measured data. The measurement model includes a few (on the order of ten) adjustable parameters and is representative of the geometry and optical properties of the specimen and the optical properties of the measurement system. The method of inverse solve includes, but is not limited to, model based regression, tomography, machine learning, or any combination thereof. In this manner, target profile parameters are estimated by solving for values of a parameterized measurement model that minimize errors between the measured optical intensities and modeled results.

In a further aspect, computing system 116 is configured to generate a structural model (e.g., geometric model, material model, or combined geometric and material model) of a measured structure of a specimen, generate an optical response model that includes at least one geometric parameter from the structural model, and resolve at least one specimen parameter value by performing a fitting analysis of optical measurement data with the optical response model. The analysis engine is used to compare the simulated optical response signals with measured data thereby allowing the determination of geometric as well as material properties of the sample. In the embodiment depicted in FIG. 1, computing system 116 is configured as a model building and analysis engine 130 configured to implement model building and analysis functionality as described herein.

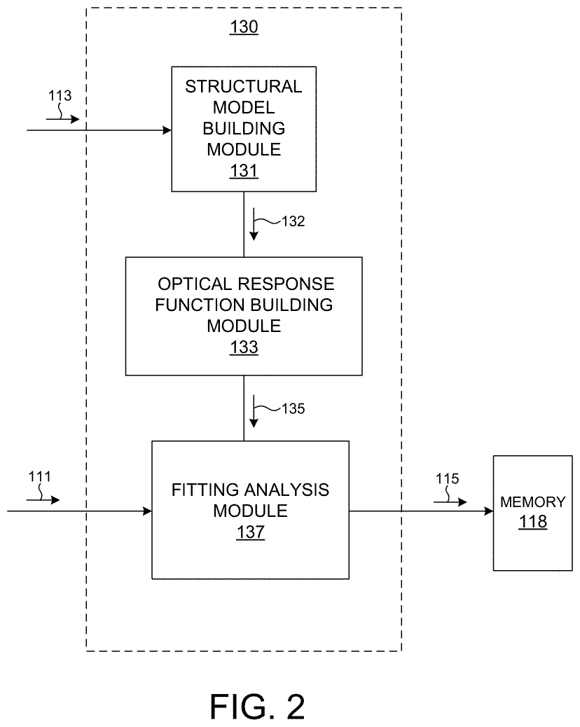

FIG. 2 is a diagram illustrative of an exemplary model building and analysis engine 130 implemented by computing system 116. As depicted in FIG. 2, model building and analysis engine 130 includes a structural model building module 131 that generates a structural model 132 of a measured semiconductor structure disposed on a specimen based in part on expected profile data 113. In some embodiments, structural model 132 also includes material properties of the specimen. The structural model 132 is received as input to optical response function building module 133. Optical response function building module 133 generates an optical response function model 135 based at least in part on the structural model 132.

Optical response function model 135 is received as input to fitting analysis module 137. The fitting analysis module 137 compares the modeled optical response with the corresponding measured data 111 to determine geometric as well as material properties of the specimen.

In some examples, fitting analysis module 137 resolves at least one specimen parameter value by performing a fitting analysis on optical measurement data 111 with the optical response model 135.

The fitting of optical metrology data is advantageous for any type of optical metrology technology that provides sensitivity to geometric and/or material parameters of interest. Specimen parameters can be deterministic (e.g., CD, SWA, etc.) or statistical (e.g., rms height of sidewall roughness, roughness correlation length, etc.) as long as proper models describing light interaction with the specimen are used.

In general, computing system 116 is configured to access model parameters in real-time, employing Real Time Critical Dimensioning (RTCD), or it may access libraries of pre-computed models for determining a value of at least one specimen parameter value associated with the specimen 114. In general, some form of CD-engine may be used to evaluate the difference between assigned CD parameters of a specimen and CD parameters associated with the measured specimen. Exemplary methods and systems for computing specimen parameter values are described in U.S. Pat. No. 7,826,071, issued on Nov. 2, 2010, to KLA-Tencor Corp., the entirety of which is incorporated herein by reference.

In addition, in some embodiments, the one or more computing systems 116 are further configured to receive expected profile data 113 from an expected profile data source 103 such as a process tool, a drawing tool operated by a user, a process simulation tool, etc. The one or more computer systems are further configured to configure structural models as described herein (e.g., structural model 132).

In some embodiments, measurement system 100 is further configured to store one or more optimized structural models 115 in a memory (e.g., carrier medium 118).

In one aspect, a model building tool, e.g., model building and analysis engines 130 and 350, generates an optimized geometric model of a semiconductor structure parameterized by a set of variables in a latent mathematical space. As described hereinbefore, the optimization of a geometric model is informed by expected profile data, i.e., an expectation of the shape of the structure of interest at one or more steps in a fabrication process flow.

In some embodiments, the model building tool receives a plurality of reference shape profiles characterizing the shape of a semiconductor structure of interest from an expected profile data source. The reference shape profiles are parameterized by a set of observable geometric variables, e.g., critical dimensions, height, ellipticity, tilt, etc. The model building tool transforms the set of observable geometric variables to a set of latent variables. The set of latent variables characterizing the reference shape profiles define the geometry of the structure of interest in an alternative mathematical space. Changes in values of the latent variables represent changes in the geometry of the structure of interest.

In general, many different sources of expected profile data are contemplated within the scope of this patent document. In some examples, an expected profile data source is a trusted metrology system. In these examples, reference shape profiles are generated by measurements of a number of different instances of a structure of interest by the trusted metrology system, e.g., a scanning electron microscope, a tunneling electron microscope, a focused ion beam measurement system, an atomic force microscope, etc.

In some examples, an expected profile data source is a semiconductor process simulation tool, such as ProETCH® etch simulation software or ProLITH® lithography and patterning simulation software available from KLA Corporation, Milpitas, Calif. (USA). In these examples, reference shape profiles are simulated by the semiconductor fabrication process simulator. In general, the set of reference profiles is simulated by randomly sampling relevant process variables within predefined ranges. In this manner, the reference shape profile data set captures the expected variation of the relevant process variables.

In some examples, an expected profile data source is a user generated specification of the reference shape profiles. In some examples, a user operates an interactive software tool, e.g., a mechanical drawing software tool, to generate reference shape profiles. In this manner, the user defines the reference shape profiles based on user experience with the fabrication process.

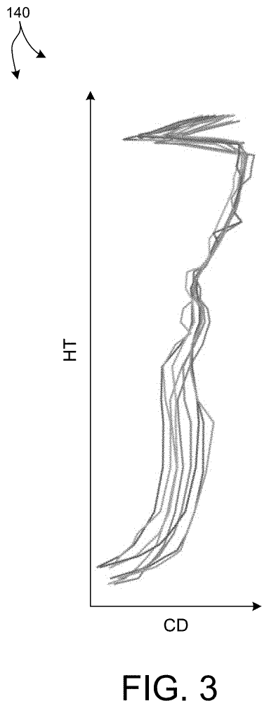

FIG. 3 is a plot 140 illustrative of a number of user generated reference shape profiles associated with a particular semiconductor structure of interest. The reference shape profiles are parameterized by a critical dimension plotted along the horizontal axis and a height dimension plotted along the vertical axis of plot 140. In the examples depicted in FIG. 3, the reference shape profiles are defined by a user based on user experience.

As illustrated in FIG. 3, reference shape profiles are parameterized by a set of observable geometric variables, e.g., height, critical dimension (CD), tilt, ellipticity, etc. Observable geometric variables are directly observable from an illustration of the geometry of the structure of interest, e.g., a shape profile.

In a further aspect, a model building tool transforms the set of observable geometric variables to a set of latent variables. The number of latent variables is smaller than the number of observable geometric variables, thus the dimension of the parameter space employed to characterize the structure of interest is reduced. In general, any process driven parameterization or combination of different parameterizations may be employed to reduce the dimension of the parameter space employed to characterize the structure of interest.

In some examples, the transformation of the set of observable geometric variables to the set of latent variables involves a principal component analysis (PCA). The PCA is a linear transformation from observable, geometric variables to a set of principle components. In these examples, the principle components are the latent variables.

In another further aspect, a model building tool generates a first set of reconstructed shape profiles based on a sampling of values of the set of latent variables. After transforming the set of observable geometric variables to the set of latent variables, new shape profiles are generated that belong to the family of reference shape profiles. New shape profiles are generated by randomly sampling from the range of the latent variables. For purposes of comparison, the sampled values of the latent variables are transformed back to values of the observable geometric variables by inverse transformation from the latent space to the observable geometric space.

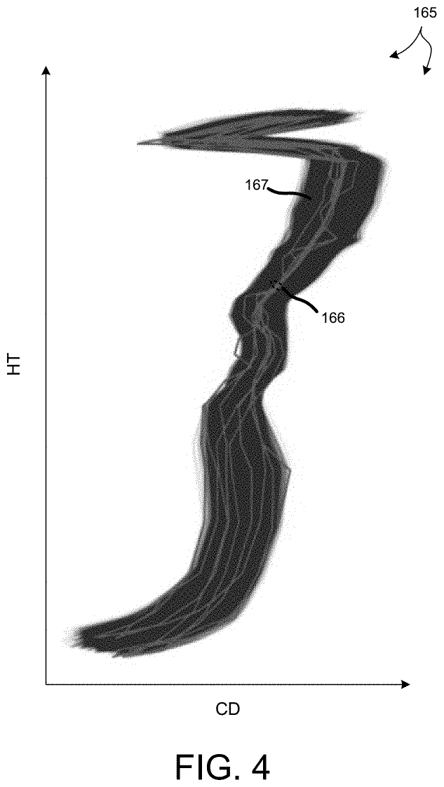

FIG. 4 is a plot 165 illustrative of a number of different reference shape profiles 166 and reconstructed shape profiles 137. The reference shape profiles 166 are the reference shape profiles depicted in FIG. 3. In addition, FIG. 4 illustrates a large number of reconstructed profiles 167. Reconstructed profiles 167 are generated by randomly sampling from the range of the latent variables. The sampled values of the latent variables are transformed back to values of the observable geometric variables by inverse transformation from the latent space to the observable geometric space. The resulting values of the observable geometric variables are plotted as reconstructed profiles 167. In this example, the latent variables, i.e., the principal components, capture changes in CD and height, simultaneously.

In another further aspect, a model building tool truncates the set of latent variables to a reduced set of latent variables based on differences between the first set of reconstructed shape profiles and the reference shape profiles. The difference between profiles reconstructed from sampled values of the latent variables and the reference shape profiles provides a quantifiable measure of the accuracy of the representation of the reference shape profiles in the latent mathematical space. In this manner, a model building tool determines the number of latent variables required to represent the reference shape profiles at a desired level of accuracy.

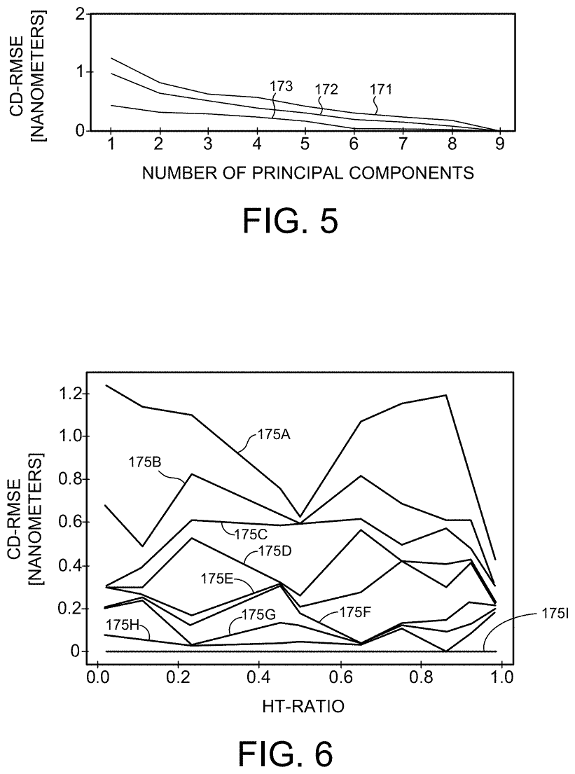

FIG. 5 is a plot illustrative of a root mean squared error measure of the differences between values of a critical dimension (CD-RMSE) associated with a set of reference shape profiles and the corresponding values of the critical dimension associated with reconstructed profiles predicted by an optimized geometric model. As depicted in FIG. 5, plotline 171 illustrates the maximum value of the set of CD-RMSE values as a function of the number of latent variables of the optimized geometric model. Plotline 172 illustrates the average value of the set of CD-RMSE values as a function of the number of latent variables of the optimized geometric model. Plotline 173 illustrates the minimum value of the set of CD-RMSE values as a function of the number of latent variables of the optimized geometric model. As depicted in FIG. 4, the CD-RMSE values drop significantly as the number of latent variables increases. Thus, an optimized geometric model is able to represent the geometry of a structure of interest with relatively few latent variables, e.g., less than 10 latent variables.

FIG. 6 is a plot illustrative of a root mean squared error measure of the differences between values of a critical dimension (CD-RMSE) associated with a set of reference shape profiles and the corresponding values of the critical dimension associated with reconstructed profiles predicted by an optimized geometric model at different heights. As depicted in FIG. 6, plotlines 171A-I illustrate the error as a function of height for an optimized geometric model parameterized by 1-9 latent variables, respectively. As depicted in FIG. 6, height is expressed as a ratio of the full height of the structure of interest. Furthermore, reconstruction error decreases significantly as the number of latent variables increases from one to nine. Again, an optimized geometric model is able to represent the geometry of a structure of interest with relatively few latent variables, e.g., less than 10 latent variables.

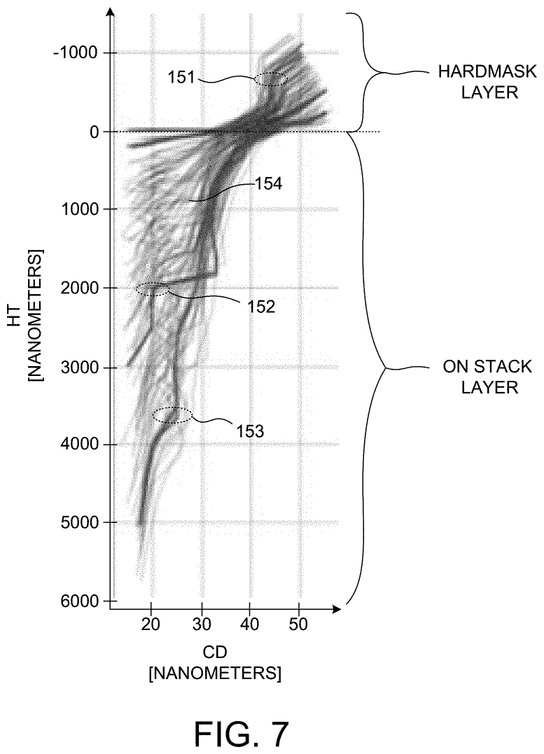

FIG. 7 is a plot illustrative of a number of reference shape profiles and a number of reconstructed shape profiles that capture different etch depths. Each reference shape profile specifies a CD value at 50 different height values in the hardmask layer and a CD value at 50 different height values in the ON stack layer. Reference shape profiles 151 characterize a shallow etch profile, i.e., expected shape profiles after a relatively short amount of etch time. In this amount of time the etch penetrates the hardmask layer, but has not significantly penetrated the ON stack layer. Reference shape profiles 152 characterize a middle etch profile, i.e., expected shape profiles after more etch time than the shallow etch. In this amount of time the etch penetrates both the hardmask layer and the ON stack layer. Reference shape profiles 153 characterize a deep etch profile, i.e., expected shape profiles after more etch time than the middle etch. In this amount of time the etch penetrates the hardmask layer and deeply penetrates the ON stack layer. As depicted in FIG. 7, as the etch depth increases, more of the hardmask layer is etched away, i.e., the CD values increase. In addition, FIG. 7 illustrates a large number of reconstructed profiles 154. Reconstructed profiles 154 are generated by randomly sampling from the range of the latent variables as described hereinbefore.

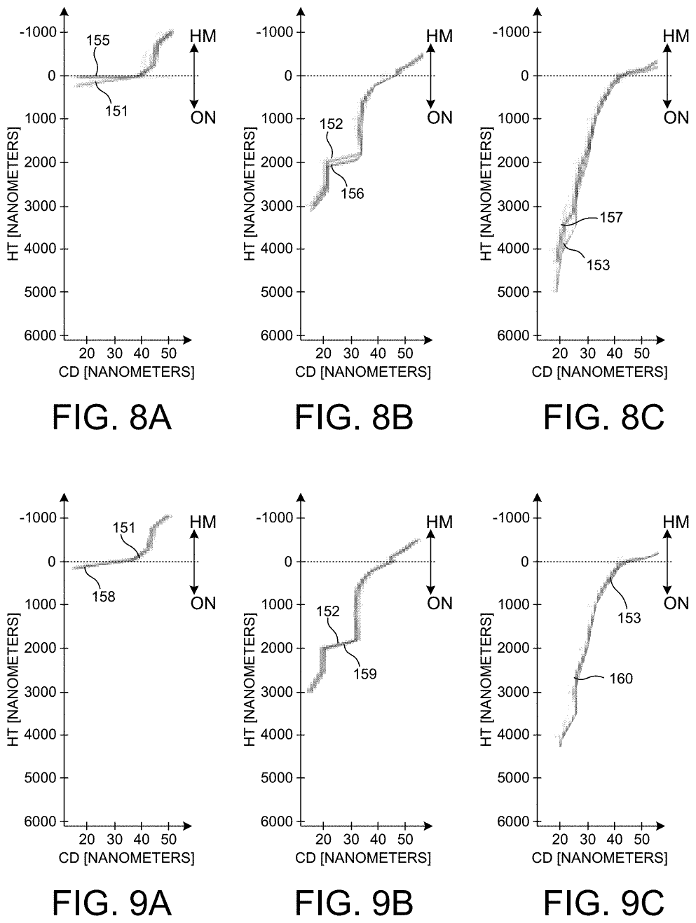

FIGS. 8A-C depict both reference shape profiles and reconstructed profiles associated with the shallow, middle, and deep etch structures depicted in FIG. 7. In the example depicted in FIGS. 8A-C, a conventional PCA is employed to define the latent variables and the number of latent variables is truncated to two principal components. The observable, geometric variables, i.e., the 50 critical dimensions in the hardmask region, the 50 critical dimensions in the ON stack region, the heights in both the hardmask region and the ON stack region, and the height ratios in both the hardmask region and the ON stack region are equally weighted. Reconstructed profiles 155, 156, and 157 are derived from the two principal components. The principal components describe changes of both height and CD of the hard mask and the ON stack.

In some examples, a weighted PCA is employed to transform the set of observable geometric variables to a set of latent variables. Weighting the observable geometric parameters improves the accuracy of the latent parameterization with a smaller number of variables. Weighted PCA parameterization enables an increased weighting on observable geometric variables that have relatively low sensitivity, more challenging accuracy requirements, or both.

In one example, a weighted PCA is employed to improve the accuracy of parameterization of a partially etched structure illustrated by the partially etched reference shape profiles depicted in FIG. 7 and FIGS. 8A-C.

FIGS. 9A-C depict both reference shape profiles and reconstructed profiles associated with the shallow, middle, and deep etch structures depicted in FIG. 7. In the example depicted in FIGS. 9A-C, a weighted PCA is employed to define the latent variables and the number of latent variables is truncated to two principal components. In the example depicted in FIGS. 9A-C, the height variables are weighted by a factor of 10 and the critical dimensions are weighted by a factor of 1. Weighting the height variables more than the critical dimension variables, increases the accuracy of height in the reconstructed profiles. As depicted in FIGS. 9A-C, reconstructed profiles 158, 159, and 160 are derived from the two principal components of the weighted PCA, and the fit to the reference shape profiles 151, 152, and 153, respectively, is better than reconstructed profiles 155, 156, and 157 derived from the unweighted PCA.

In some examples, the transformation of the set of observable geometric variables to the set of latent variables involves a trained autoencoder. The trained autoencoder includes an encoder that transforms observable geometric variables to latent variables and a decoder that transforms the latent variables back to the observable geometric variables. In general, the trained autoencoder is a non-linear transformation that models a more complex latent space that more accurately models the reference shape profiles with fewer latent variables than a linear transformation, such as PCA. In this manner, a trained autoencoder may be more computationally efficient and more accurate than a PCA, particularly when reference profile geometry is more complex.

In some embodiments, the trained autoencoder includes a neural network trained to transform reference shape profiles parameterized by a relatively large number of observable geometric variables to a latent space parameterized by a relatively small number of latent variables, i.e., the encoder, and a neural network trained to transform values of the latent variables back to values of the observable geometric variables, i.e., the decoder. Profiles can be generated using random values of the latent variables within the limits of the latent space. In some examples, an autoencoder is a variational autoencoder. In these examples, the latent space is trained to have a unit normal distribution and random profiles can be generated using a normal distribution.

In some examples, the transformation of the set of observable geometric variables to the set of latent variables involves a hybrid parameterization including a latent space parameterization as described hereinbefore and a function fit to differences between the reference shape profiles and reconstructed profiles derived from values of the latent variables. The summation of the latent space parameterization and functional fit provides a more accurate representation of the reference shape profiles with a relatively small number of independent variables. In general, any suitable mathematical function may be the basis for the functional fit, including, but not limited to a spline function, a Chebyshev polynomial function, a Fast Fourier Transform function, a Discrete Cosine Transform function, a user defined parameterization, etc.

In general, a latent space parameterization accurately captures profiles present in the training set of reference shape profiles. However, there may be additional profile variations induced by process variations that are not captured in the training set of reference shape profiles, and thus not captured by the latent space parameterization. In these examples, profile variation may be more accurately characterized by a combination of the latent space parameterization and one or more general purpose mathematical functions, e.g., Chebyshev polynomial curves. In this manner, the hybrid parameterization effectively extends the process range by introducing a general purpose parameterization to the process based latent space parameterization.

In another further aspect, a model building tool generates a set of reconstructed shape profiles based on a sampling of values of the latent variables as described hereinbefore. In addition, the model building tool fits a mathematical function, e.g., a curve, to differences between the reference shape profiles and the reconstructed shape profiles. The model building tool then generates another set of reconstructed shape profiles based on a sum of the reconstructed shape profiles derived from values of the latent variables and the fitted curve. The resulting reconstructed shape profiles can be employed to train a measurement model.

In another further aspect, a model building tool extends the range of values of one or more of the set of observable geometric variables to effectively expand the range of training set of reference shape profiles. The extended training set of reference shape profiles is then employed as the basis for generating the transformation to latent space, e.g., by PCA, trained autoencoder, etc. Extending the range of observable geometric variables employed as the basis for generating the transformation to the latent space effectively expands the range of process variations contemplated within the process space. This enhances the robustness of the latent space to process variations, although generally at the cost of a larger number of latent variables required to accurately represent the extended range of reference shape profiles.

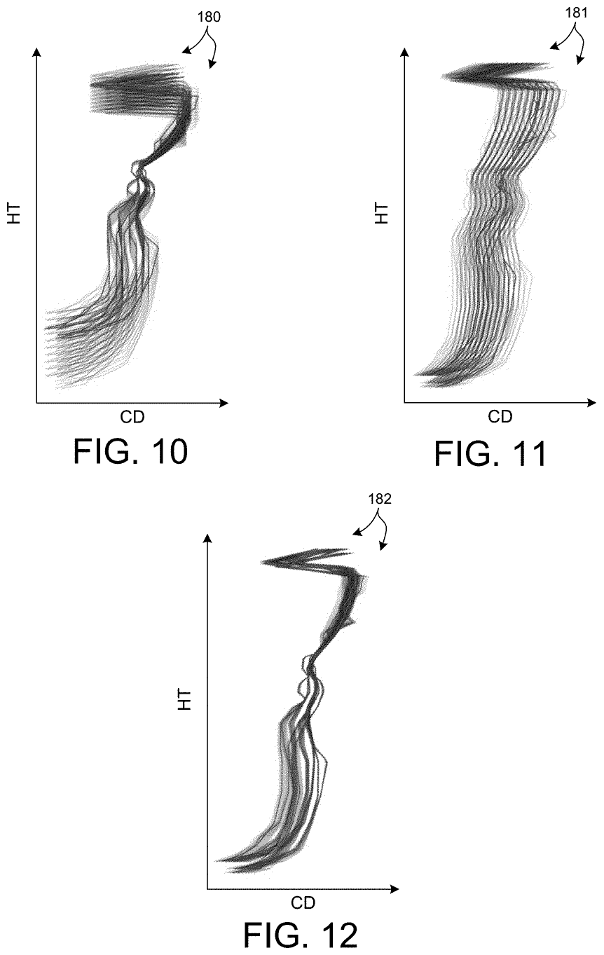

FIG. 10 is a plot 180 illustrative of an extended training set of reference shape profiles including a number of reference shape profiles extended by scaling the reference profile height values by 20%.

FIG. 11 is a plot 181 illustrative of an extended training set of reference shape profiles including a number of reference shape profiles extended by shifting the range of critical dimensions by 20%.

FIG. 12 is a plot 182 illustrative of an extended training set of reference shape profiles including a number of reference shape profiles extended by scaling the range of critical dimensions by 20%.

As illustrated in FIGS. 10-12, the range of values of observable geometric variables may be extended by scaling their value, shifting their values, or any combination thereof. However, in general, any number of different extensions of the training set of reference shape profiles, in any combination, may be contemplated within the scope of this patent document.

In another further aspect, a model building tool eliminates non-physical shape profiles from reconstructed shape profiles generated from the set of latent variables.

As described hereinbefore, reconstructed shape profiles are generated by sampling the latent variables. When the latent variables are trained on a limited set of reference shape profiles, it is possible to generate unphysical shape profiles that may arise from random combinations of latent variables. The presence of non-physical profiles in reconstructed profile data can be problematic when training measurement models employed to fit measured spectra to shape profiles. To reduce this risk, a model building tool eliminates non-physical profiles from the reconstructed profile data set employed to train a measurement model.

In some examples, non-physical profiles are identified based on values of one or more derivatives of the reconstructed shape profile. Each derivative value is compared to a corresponding predetermined range of acceptable values, and if the calculated derivative value is outside the range of acceptable values, the reconstructed shape profile is eliminated. In one example, a reconstructed shape profile is generated in latent space and transformed back to the space of observable, geometric variables. In one example, a critical dimension of a reconstructed shape profile is expressed as a function of height. In this example, the one or more derivatives of CD with respect to height are calculated, e.g., dCD/dH, d²CD/dH², etc. If the values of any of the derivatives are outside the corresponding acceptable range of threshold values, the reconstructed shape profile is eliminated.

In some examples, reconstructed shape profiles are generated by sampling a subspace of the latent space spanned by the set of latent variables. In one example, sample values of the set of latent variables are selected from a hypersphere in latent space, rather than a hypercube. In other words, only values of the set of latent variables within a fixed distance from the center of the latent space are selected to generate reconstructed shape profiles, rather than extreme values of the set of latent variables.

In some examples, the values of the observable geometric variables associated with each reconstructed shape profile are compared to predetermined acceptable ranges of values of each of the observable geometric variables, and if any of the values of the observable geometric variables associated with a particular reconstructed profile lie outside the acceptable range of values, the reconstructed shape profile is eliminated. In one example, ranges of acceptable CD and height are established, and the values of CD and height associated with each reconstructed shape profile are compared to the acceptable ranges. If the values of CD or height associated with a particular reconstructed shape profile lies outside the acceptable, range, the reconstructed shape profile is eliminated.

In another further aspect, a model building tool trains a measurement model based at least in part on the reconstructed shape profiles derived from the optimized geometric model of the structure under measurement. A large number of reconstructed shape profiles spanning the relevant process variations are efficiently generated based on the optimized geometric model. A measurement simulation tool is employed to generate synthetic measurement data, e.g., spectra, images, electron density maps, etc., associated with each different reconstructed shape profile. The reconstructed shape profiles and corresponding sets of measurement data comprise a training data set employed to train a measurement model, such as optical response function model 135 depicted in FIG. 2, X-ray scatterometry response model 355, or a machine learning based measurement model.

In another further aspect, a model building tool employs a trained measurement model to estimate values of observable geometric parameters of interest associated with a structure under measurement.

In these examples, measurements are performed by a metrology system, such as metrology systems 100, 300, and 500 depicted in FIGS. 1, 13, and 15, respectively. In general, an instance of a semiconductor structure of interest is illuminated with an amount of energy. An amount of measurement data is detected in response to the amount of energy. Values of the set of latent variables characterizing the semiconductor structure of interest are estimated based on a fitting of the trained measurement model to the amount of measurement data. Finally, the estimated values of the set of latent variables are transformed to values of the set of observable geometric variables characterizing the structure of interest. The estimated values of the latent variables are transformed back to values of the observable geometric variables by inverse transformation from the latent space to the observable geometric space. The inverse transformation is the inverse of the transformation employed to determine the set of latent variables from the set of observable geometric variables, e.g., an inverse of the forward PCA transformation, a trained decoder, etc.

Measurements employing an optimized geometric model may be performed by many different semiconductor measurement systems. By way of non-limiting example, a rotating polarizer spectroscopic ellipsometer, a rotating polarizer, rotating compensator spectroscopic ellipsometer, a rotating compensator, rotating compensator spectroscopic ellipsometer, a soft x-ray based reflectometer, a small-angle x-ray scatterometer, or any combination thereof, may employ an optimized geometric model as described herein.

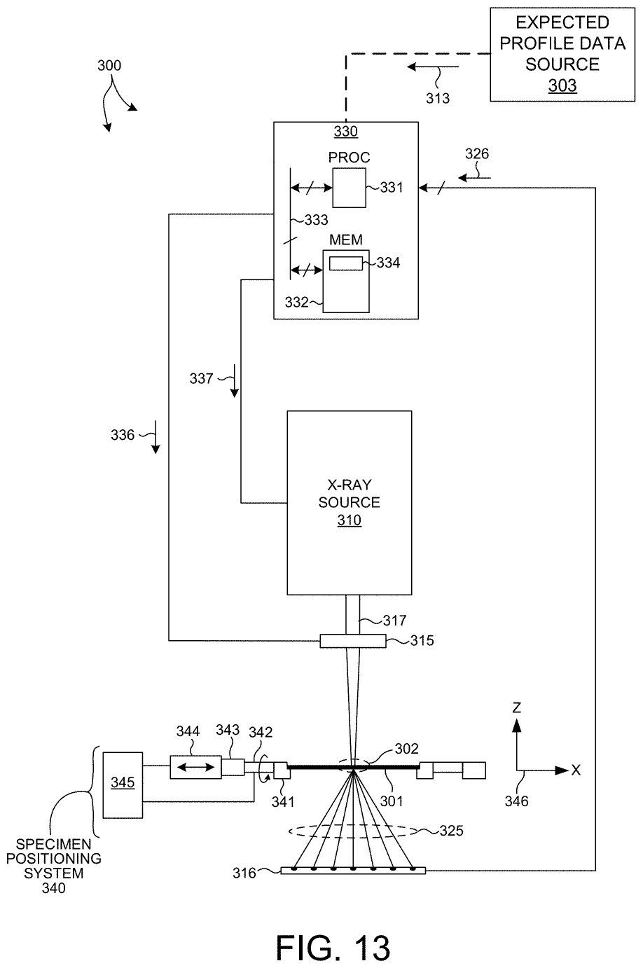

By way of example, FIG. 13 illustrates an embodiment of an x-ray metrology tool 300 employing an optimized geometric model for measuring characteristics of a specimen in accordance with the exemplary methods presented herein. As shown in FIG. 13, the system 300 may be used to perform x-ray scatterometry measurements over an inspection area 302 of a specimen 301 disposed on a specimen positioning system 340.

In the depicted embodiment, metrology tool 300 includes an x-ray illumination source 310 configured to generate x-ray radiation suitable for x-ray scatterometry measurements. In some embodiments, the x-ray illumination system 310 is configured to generate wavelengths between 0.01 nanometers and 1 nanometer. X-ray illumination source 310 produces an x-ray beam 317 incident on inspection area 302 of specimen 301.

In general, any suitable high-brightness x-ray illumination source capable of generating high brightness x-rays at flux levels sufficient to enable high-throughput metrology may be contemplated to supply x-ray illumination for x-ray scatterometry measurements. In some embodiments, an x-ray source includes a tunable monochromator that enables the x-ray source to deliver x-ray radiation at different, selectable wavelengths.

In some embodiments, one or more x-ray sources emitting radiation with photon energy greater than 15 keV are employed to ensure that the x-ray source supplies light at wavelengths that allow sufficient transmission through the entire device as well as the wafer substrate. By way of non-limiting example, any of a particle accelerator source, a liquid anode source, a rotating anode source, a stationary, solid anode source, a microfocus source, a microfocus rotating anode source, and an inverse Compton source may be employed as x-ray source 310. In one example, an inverse Compton source available from Lyncean Technologies, Inc., Palo Alto, Calif. (USA) may be contemplated. Inverse Compton sources have an additional advantage of being able to produce x-rays over a range of photon energies, thereby enabling the x-ray source to deliver x-ray radiation at different, selectable wavelengths. In some embodiments, an x-ray source includes an electron beam source configured to bombard solid or liquid targets to stimulate x-ray radiation.

In some embodiments, the profile of the incident x-ray beam is controlled by one or more apertures, slits, or a combination thereof. In a further embodiment, the apertures, slits, or both, are configured to rotate in coordination with the orientation of the specimen to optimize the profile of the incident beam for each angle of incidence, azimuth angle, or both.

As depicted in FIG. 13, x-ray optics 315 shape and direct incident x-ray beam 317 to specimen 301. In some examples, x-ray optics 315 include an x-ray monochromator to monochromatize the x-ray beam that is incident on the specimen 301. In one example, a crystal monochromator such as a Loxley-Tanner-Bowen monochromator is employed to monochromatize the beam of x-ray radiation. In some examples, x-ray optics 315 collimate or focus the x-ray beam 317 onto inspection area 302 of specimen 301 to less than 1 milliradian divergence using multilayer x-ray optics. In some embodiments, x-ray optics 315 includes one or more x-ray collimating mirrors, x-ray apertures, x-ray beam stops, refractive x-ray optics, diffractive optics such as zone plates, specular x-ray optics such as grazing incidence ellipsoidal mirrors, polycapillary optics such as hollow capillary x-ray waveguides, multilayer optics, or systems, or any combination thereof. Further details are described in U.S. Patent Publication No. 2015/0110249, the content of which is incorporated herein by reference it its entirety.

In general, the focal plane of the illumination optics system is optimized for each measurement application. In this manner, system 300 is configured to locate the focal plane at various depths within the specimen depending on the measurement application.

X-ray detector 316 collects x-ray radiation 325 scattered from specimen 301 and generates an output signal 326 indicative of properties of specimen 301 that are sensitive to the incident x-ray radiation in accordance with an x-ray scatterometry measurement modality. In some embodiments, scattered x-rays 325 are collected by x-ray detector 316 while specimen positioning system 340 locates and orients specimen 301 to produce angularly resolved scattered x-rays.

In some embodiments, an x-ray scatterometry system includes one or more photon counting detectors with high dynamic range (e.g., greater than 105) and thick, highly absorptive crystal substrates that absorb the direct beam (i.e., zero order beam) without damage and with minimal parasitic backscattering. In some embodiments, a single photon counting detector detects the position and number of detected photons.

In some embodiments, the x-ray detector resolves one or more x-ray photon energies and produces signals for each x-ray energy component indicative of properties of the specimen. In some embodiments, the x-ray detector 316 includes any of a CCD array, a microchannel plate, a photodiode array, a microstrip proportional counter, a gas filled proportional counter, a scintillator, or a fluorescent material.

In this manner the X-ray photon interactions within the detector are discriminated by energy in addition to pixel location and number of counts. In some embodiments, the X-ray photon interactions are discriminated by comparing the energy of the X-ray photon interaction with a predetermined upper threshold value and a predetermined lower threshold value. In one embodiment, this information is communicated to computing system 330 via output signals 326 for further processing and storage.

In a further aspect, x-ray scatterometry system 300 is employed to determine properties of a specimen (e.g., structural parameter values) based on one or more measured intensities. As depicted in FIG. 13, metrology system 300 includes a computing system 330 employed to acquire signals 326 generated by detector 316 and determine properties of the specimen based at least in part on the acquired signals.

In some embodiments, it is desirable to perform measurements at different orientations described by rotations about the x and y axes indicated by coordinate system 346 depicted in FIG. 13. This increases the precision and accuracy of measured parameters and reduces correlations among parameters by extending the number and diversity of data sets available for analysis to include a variety of large-angle, out of plane orientations. Measuring specimen parameters with a deeper, more diverse data set also reduces correlations among parameters and improves measurement accuracy. For example, in a normal orientation, x-ray scatterometry is able to resolve the critical dimension of a feature, but is largely insensitive to sidewall angle and height of a feature. However, by collecting measurement data over a broad range of out of plane angular positions, the sidewall angle and height of a feature can be resolved.

As illustrated in FIG. 13, metrology tool 300 includes a specimen positioning system 340 configured to both align specimen 301 and orient specimen 301 over a large range of out of plane angular orientations with respect the scatterometer. In other words, specimen positioning system 340 is configured to rotate specimen 301 over a large angular range about one or more axes of rotation aligned in-plane with the surface of specimen 301. In some embodiments, specimen positioning system is configured to rotate specimen 301 within a range of at least 120 degrees about one or more axes of rotation aligned in-plane with the surface of specimen 301. In this manner, angle resolved measurements of specimen 301 are collected by metrology system 300 over any number of locations on the surface of specimen 301. In one example, computing system 330 communicates command signals to motion controller 345 of specimen positioning system 340 that indicate the desired position of specimen 301. In response, motion controller 345 generates command signals to the various actuators of specimen positioning system 340 to achieve the desired positioning of specimen 301.

By way of non-limiting example, as illustrated in FIG. 13, specimen positioning system 340 includes an edge grip chuck 341 to fixedly attach specimen 301 to specimen positioning system 340. A rotational actuator 342 is configured to rotate edge grip chuck 341 and the attached specimen 301 with respect to a perimeter frame 343. In the depicted embodiment, rotational actuator 342 is configured to rotate specimen 301 about the x-axis of the coordinate system 346 illustrated in FIG. 13. As depicted in FIG. 13, a rotation of specimen 301 about the z-axis is an in plane rotation of specimen 301. Rotations about the x-axis and the y-axis (not shown) are out of plane rotations of specimen 301 that effectively tilt the surface of the specimen with respect to the metrology elements of metrology system 300. Although it is not illustrated, a second rotational actuator is configured to rotate specimen 301 about the y-axis. A linear actuator 344 is configured to translate perimeter frame 343 in the x-direction. Another linear actuator (not shown) is configured to translate perimeter frame 343 in the y-direction. In this manner, every location on the surface of specimen 301 is available for measurement over a range of out of plane angular positions. For example, in one embodiment, a location of specimen 301 is measured over several angular increments within a range of −45 degrees to +45 degrees with respect to the normal orientation of specimen 301.

In general, specimen positioning system 340 may include any suitable combination of mechanical elements to achieve the desired linear and angular positioning performance, including, but not limited to goniometer stages, hexapod stages, angular stages, and linear stages.

In some examples, metrology based on x-ray scatterometry involves determining the dimensions of the sample by the inverse solution of a pre-determined measurement model with the measured data. The measurement model includes a few (on the order of ten) adjustable parameters and is representative of the geometry and optical properties of the specimen and the optical properties of the measurement system. The method of inverse solve includes, but is not limited to, model based regression, tomography, machine learning, or any combination thereof. In this manner, target profile parameters are estimated by solving for values of a parameterized measurement model that minimize errors between the measured scattered x-ray intensities and modeled results.

In a further aspect, computing system 330 is configured to generate a structural model (e.g., geometric model, material model, or combined geometric and material model) of a measured structure of a specimen, generate a x-ray scatterometry response model that includes at least one geometric parameter from the structural model, and resolve at least one specimen parameter value by performing a fitting analysis of x-ray scatterometry measurement data with the x-ray scatterometry response model. The analysis engine is used to compare the simulated x-ray scatterometry signals with measured data thereby allowing the determination of geometric as well as material properties such as electron density of the sample. In the embodiment depicted in FIG. 13, computing system 330 is configured as a model building and analysis engine 350 configured to implement model building and analysis functionality as described herein.

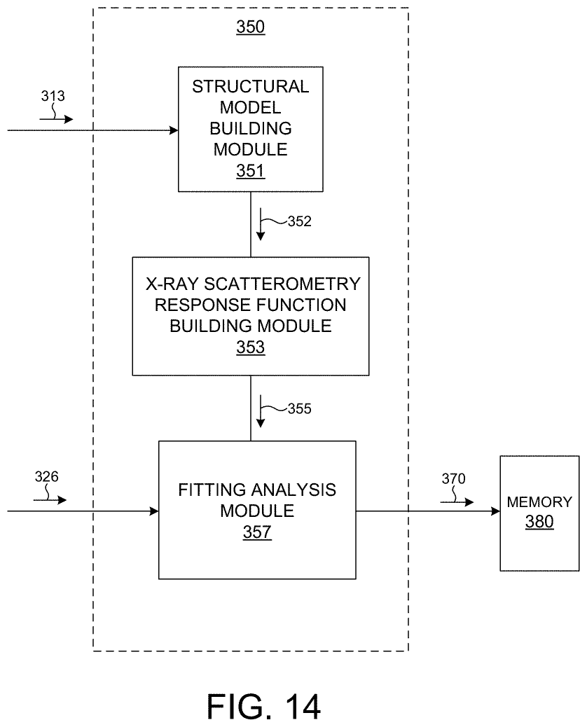

FIG. 14 is a diagram illustrative of an exemplary model building and analysis engine 350 implemented by computing system 330. As depicted in FIG. 14, model building and analysis engine 350 includes a structural model building module 351 that generates a structural model 352 of a measured semiconductor structure disposed on a specimen based in part on reference shape profiles 313 received from an expected profile data source 303 as described herein. In some embodiments, structural model 352 also includes material properties of the specimen. The structural model 352 is received as input to x-ray scatterometry response function building module 353. X-ray scatterometry response function building module 353 generates a x-ray scatterometry response function model 355 based at least in part on the structural model 352. X-ray scatterometry response function model 355 is received as input to fitting analysis module 357. The fitting analysis module 357 compares the modeled x-ray scatterometry response with the corresponding measured data 326 to determine geometric as well as material properties of the specimen.

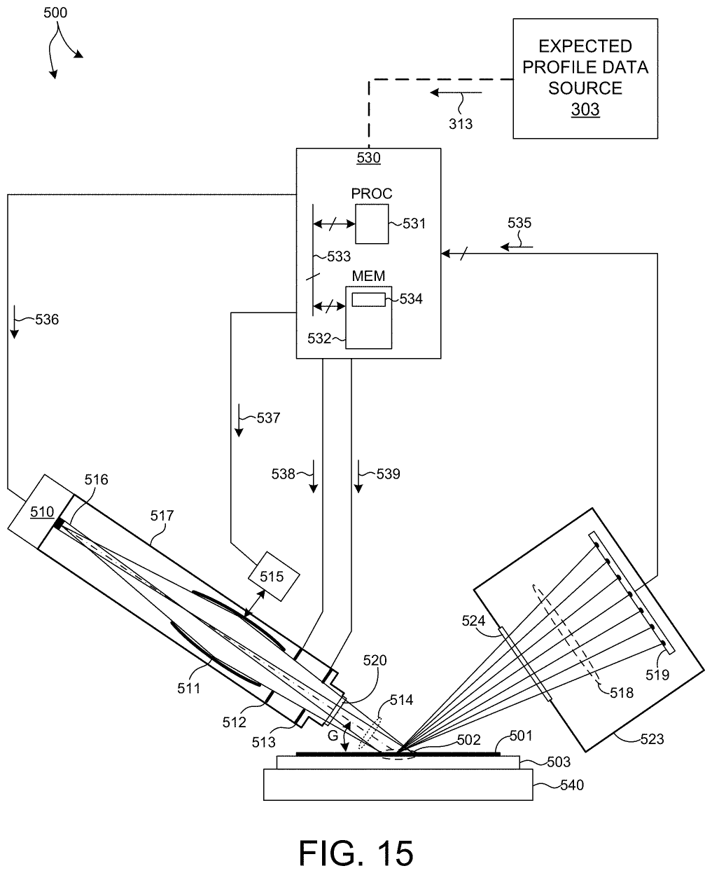

FIG. 15 illustrates an embodiment of a soft x-ray reflectometry (SXR) metrology tool 500 for measuring characteristics of a specimen. In some embodiments, SXR measurements of a semiconductor wafer are performed over a range of wavelengths, angles of incidence, and azimuth angles with a small beam spot size (e.g., less than 50 micrometers across the effective illumination spot). In one aspect, the SXR measurements are performed with x-ray radiation in the soft x-ray region (i.e., 30-3000 eV) at grazing angles of incidence in the range of 5-20 degrees. Grazing angles for a particular measurement application are selected to achieve a desired penetration into the structure under measurement and maximize measurement information content with a small beam spot size (e.g., less than 50 micrometers).

As illustrated in FIG. 15, the system 500 performs SXR measurements over a measurement area 502 of a specimen 501 illuminated by an incident illumination beam spot.

In the depicted embodiment, metrology tool 500 includes an x-ray illumination source 510, focusing optics 511, beam divergence control slit 512, and slit 513. The x-ray illumination source 510 is configured to generate Soft X-ray radiation suitable for SXR measurements. X-ray illumination source 510 is a polychromatic, high-brightness, large etendue source. In some embodiments, the x-ray illumination source 510 is configured to generate x-ray radiation in a range between 30-3000 electron-volts. In general, any suitable high-brightness x-ray illumination source capable of generating high brightness Soft X-ray at flux levels sufficient to enable high-throughput, inline metrology may be contemplated to supply x-ray illumination for SXR measurements.

In some embodiments, an x-ray source includes a tunable monochromator that enables the x-ray source to deliver x-ray radiation at different, selectable wavelengths. In some embodiments, one or more x-ray sources are employed to ensure that the x-ray source supplies light at wavelengths that allow sufficient penetration into the specimen under measurement.

In some embodiments, illumination source 510 is a high harmonic generation (HHG) x-ray source. In some other embodiments, illumination source 510 is a wiggler/undulator synchrotron radiation source (SRS). An exemplary wiggler/undulator SRS is described in U.S. Pat. Nos. 8,941,336 and 8,749,179, the contents of which are incorporated herein by reference in their entireties.

In some other embodiments, illumination source 110 is a laser produced plasma (LPP) light source. In some of these embodiments the LPP light source includes any of Xenon, Krypton, Argon, Neon, and Nitrogen emitting materials. In general, the selection of a suitable LPP target material is optimized for brightness in resonant Soft X-ray regions. For example, plasma emitted by Krypton provides high brightness at the Silicon K-edge. In another example, plasma emitted by Xenon provides high brightness throughout the entire Soft X-ray region of (80-3000 eV). As such, Xenon is a good choice of emitting material when broadband Soft X-ray illumination is desired.

LPP target material selection may also be optimized for reliable and long lifetime light source operation. Noble gas target materials such as Xenon, Krypton, and Argon are inert and can be reused in a closed loop operation with minimum or no decontamination processing. An exemplary Soft X-ray illumination source is described in U.S. patent application Ser. No. 15/867,633, the content of which is incorporated herein by reference in its entirety.

In a further aspect, the wavelengths emitted by the illumination source (e.g., illumination source 510) are selectable. In some embodiments, illumination source 510 is a LPP light source controlled by computing system 530 to maximize flux in one or more selected spectral regions. Laser peak intensity at the target material controls the plasma temperature and thus the spectral region of emitted radiation. Laser peak intensity is varied by adjusting pulse energy, pulse width, or both. In one example, a 100 picosecond pulse width is suitable for generating Soft X-ray radiation. As depicted in FIG. 15, computing system 530 communicates command signals 536 to illumination source 510 that cause illumination source 510 to adjust the spectral range of wavelengths emitted from illumination source 510. In one example, illumination source 510 is a LPP light source, and the LPP light source adjusts any of a pulse duration, pulse frequency, and target material composition to realize a desired spectral range of wavelengths emitted from the LPP light source.

By way of non-limiting example, any of a particle accelerator source, a liquid anode source, a rotating anode source, a stationary, solid anode source, a microfocus source, a microfocus rotating anode source, a plasma based source, and an inverse Compton source may be employed as x-ray illumination source 510.

Exemplary x-ray sources include electron beam sources configured to bombard solid or liquid targets to stimulate x-ray radiation. Methods and systems for generating high brightness, liquid metal x-ray illumination are described in U.S. Pat. No. 7,929,667, issued on Apr. 19, 2011, to KLA-Tencor Corp., the entirety of which is incorporated herein by reference.

X-ray illumination source 510 produces x-ray emission over a source area having finite lateral dimensions (i.e., non-zero dimensions orthogonal to the beam axis. In one aspect, the source area of illumination source 510 is characterized by a lateral dimension of less than 20 micrometers. In some embodiments, the source area is characterized by a lateral dimension of 10 micrometers or less. Small source size enables illumination of a small target area on the specimen with high brightness, thus improving measurement precision, accuracy, and throughput.

In general, x-ray optics shape and direct x-ray radiation to specimen 501. In some examples, the x-ray optics collimate or focus the x-ray beam onto measurement area 502 of specimen 501 to less than 1 milliradian divergence using multilayer x-ray optics. In some embodiments, the x-ray optics include one or more x-ray collimating mirrors, x-ray apertures, x-ray beam stops, refractive x-ray optics, diffractive optics such as zone plates, Schwarzschild optics, Kirkpatrick-Baez optics, Montel optics, Wolter optics, specular x-ray optics such as ellipsoidal mirrors, polycapillary optics such as hollow capillary x-ray waveguides, multilayer optics or systems, or any combination thereof. Further details are described in U.S. Patent Publication No. 2015/0110249, the content of which is incorporated herein by reference it its entirety.

As depicted in FIG. 15, focusing optics 511 focuses source radiation onto a metrology target located on specimen 501. The finite lateral source dimension results in finite spot size 502 on the target defined by the rays 516 coming from the edges of the source and any beam shaping provided by beam slits 512 and 513.

In some embodiments, focusing optics 511 includes elliptically shaped focusing optical elements. In the embodiment depicted in FIG. 15, the magnification of focusing optics 511 at the center of the ellipse is approximately one. As a result, the illumination spot size projected onto the surface of specimen 501 is approximately the same size as the illumination source, adjusted for beam spread due to the nominal grazing incidence angle (e.g., 5-20 degrees).

In a further aspect, focusing optics 511 collect source emission and select one or more discrete wavelengths or spectral bands, and focus the selected light onto specimen 501 at grazing angles of incidence in the range 5-20 degrees.

The nominal grazing incidence angle is selected to achieve a desired penetration of the metrology target to maximize signal information content while remaining within metrology target boundaries. The critical angle of hard x-rays is very small, but the critical angle of soft x-rays is significantly larger. As a result of this additional measurement flexibility SXR measurements probe more deeply into the structure with less sensitivity to the precise value of the grazing incidence angle.

In some embodiments, focusing optics 511 include graded multi-layers that select desired wavelengths or ranges of wavelengths for projection onto specimen 501. In some examples, focusing optics 511 includes a graded multi-layer structure (e.g., layers or coatings) that selects one wavelength and projects the selected wavelength onto specimen 501 over a range of angles of incidence. In some examples, focusing optics 511 includes a graded multi-layer structure that selects a range of wavelengths and projects the selected wavelengths onto specimen 501 over one angle of incidence. In some examples, focusing optics 511 includes a graded multi-layer structure that selects a range of wavelengths and projects the selected wavelengths onto specimen 501 over a range of angles of incidence.

Graded multi-layered optics are preferred to minimize loss of light that occurs when single layer grating structures are too deep. In general, multi-layer optics select reflected wavelengths. The spectral bandwidth of the selected wavelengths optimizes flux provided to specimen 501, information content in the measured diffracted orders, and prevents degradation of signal through angular dispersion and diffraction peak overlap at the detector. In addition, graded multi-layer optics are employed to control divergence. Angular divergence at each wavelength is optimized for flux and minimal spatial overlap at the detector.

In some examples, graded multi-layer optics select wavelengths to enhance contrast and information content of diffraction signals from specific material interfaces or structural dimensions. For example, the selected wavelengths may be chosen to span element-specific resonance regions (e.g., Silicon K-edge, Nitrogen, Oxygen K-edge, etc.). In addition, in these examples, the illumination source may also be tuned to maximize flux in the selected spectral region (e.g., HHG spectral tuning, LPP laser tuning, etc.)

In some embodiments, focusing optics 511 include a plurality of reflective optical elements each having an elliptical surface shape. Each reflective optical element includes a substrate and a multi-layer coating tuned to reflect a different wavelength or range of wavelengths. In some embodiments, a plurality of reflective optical elements (e.g., 1-5) each reflecting a different wavelength or range of wavelengths are arranged at each angle of incidence. In a further embodiment, multiple sets (e.g., 2-5) of reflective optical elements each reflecting a different wavelength or range of wavelengths are arranged each at set at a different angle of incidence. In some embodiments, the multiple sets of reflective optical elements simultaneously project illumination light onto specimen 501 during measurement. In some other embodiments, the multiple sets of reflective optical elements sequentially project illumination light onto specimen 501 during measurement. In these embodiments, active shutters or apertures are employed to control the illumination light projected onto specimen 501.

In some embodiments, focusing optics 511 focus light at multiple wavelengths, azimuths and AOI on the same metrology target area.

In a further aspect, the ranges of wavelengths, AOI, Azimuth, or any combination thereof, projected onto the same metrology area, are adjusted by actively positioning one or more mirror elements of the focusing optics. As depicted in FIG. 15, computing system 530 communicates command signals to actuator system 515 that causes actuator system 515 to adjust the position, alignment, or both, of one or more of the optical elements of focusing optics 511 to achieve the desired ranges of wavelengths, AOI, Azimuth, or any combination thereof, projected onto specimen 501.

In general, the angle of incidence is selected for each wavelength to optimize penetration and absorption of the illumination light by the metrology target under measurement. In many examples, multiple layer structures are measured and angle of incidence is selected to maximize signal information associated with the desired layers of interest. In the example of overlay metrology, the wavelength(s) and angle(s) of incidence are selected to maximize signal information resulting from interference between scattering from the previous layer and the current layer. In addition, azimuth angle is also selected to optimize signal information content. In addition, azimuth angle is selected to ensure angular separation of diffraction peaks at the detector.

In a further aspect, a SXR metrology system (e.g., metrology tool 500) includes one or more beam slits or apertures to shape the illumination beam 514 incident on specimen 501 and selectively block a portion of illumination light that would otherwise illuminate a metrology target under measurement. One or more beam slits define the beam size and shape such that the x-ray illumination spot fits within the area of the metrology target under measurement. In addition, one or more beam slits define illumination beam divergence to minimize overlap of diffraction orders on the detector.

In another further aspect, a SXR metrology system (e.g., metrology tool 500) includes one or more beam slits or apertures to select a set of illumination wavelengths that simultaneously illuminate a metrology target under measurement. In some embodiments, illumination including multiple wavelengths is simultaneously incident on a metrology target under measurement. In these embodiments, one or more slits are configured to pass illumination including multiple illumination wavelengths. In general, simultaneous illumination of a metrology target under measurement is preferred to increase signal information and throughput. However, in practice, overlap of diffraction orders at the detector limits the range of illumination wavelengths. In some embodiments, one or more slits are configured to sequentially pass different illumination wavelengths. In some examples, sequential illumination at larger angular divergence provides higher throughput because the signal to noise ratio for sequential illumination may be higher compared to simultaneous illumination when beam divergence is larger. When measurements are performed sequentially the problem of overlap of diffraction orders is not an issue. This increases measurement flexibility and improves signal to noise ratio.

FIG. 15 depicts a beam divergence control slit 512 located in the beam path between focusing optics 511 and beam shaping slit 513. Beam divergence control slit 512 limits the divergence of the illumination provided to the specimen under measurement. Beam shaping slit 513 is located in the beam path between beam divergence control slit 512 and specimen 501. Beam shaping slit 513 further shapes the incident beam 514 and selects the illumination wavelength(s) of incident beam 514. Beam shaping slit 513 is located in the beam path immediately before specimen 501. In one aspect, the slits of beam shaping slit 513 are located in close proximity to specimen 501 to minimize the enlargement of the incident beam spot size due to beam divergence defined by finite source size.

In some embodiments, beam shaping slit 513 includes multiple, independently actuated beam shaping slits. In one embodiment, beam shaping slit 513 includes four independently actuated beam shaping slits. These four beams shaping slits effectively block a portion of the incoming beam and generate an illumination beam 514 having a box shaped illumination cross-section.

Slits of beam shaping slit 513 are constructed from materials that minimize scattering and effectively block incident radiation. Exemplary materials include single crystal materials such as Germanium, Gallium Arsenide, Indium Phosphide, etc. Typically, the slit material is cleaved along a crystallographic direction, rather than sawn, to minimize scattering across structural boundaries. In addition, the slit is oriented with respect to the incoming beam such that the interaction between the incoming radiation and the internal structure of the slit material produces a minimum amount of scattering. The crystals are attached to each slit holder made of high density material (e.g., tungsten) for complete blocking of the x-ray beam on one side of the slit.

X-ray detector 519 collects x-ray radiation 518 scattered from specimen 501 and generates an output signals 535 indicative of properties of specimen 501 that are sensitive to the incident x-ray radiation in accordance with a SXR measurement modality. In some embodiments, scattered x-rays 518 are collected by x-ray detector 519 while specimen positioning system 540 locates and orients specimen 501 to produce angularly resolved scattered x-rays.

In some embodiments, a SXR system includes one or more photon counting detectors with high dynamic range (e.g., greater than 105). In some embodiments, a single photon counting detector detects the position and number of detected photons.

In some embodiments, the x-ray detector resolves one or more x-ray photon energies and produces signals for each x-ray energy component indicative of properties of the specimen. In some embodiments, the x-ray detector 119 includes any of a CCD array, a microchannel plate, a photodiode array, a microstrip proportional counter, a gas filled proportional counter, a scintillator, or a fluorescent material.

In this manner the X-ray photon interactions within the detector are discriminated by energy in addition to pixel location and number of counts. In some embodiments, the X-ray photon interactions are discriminated by comparing the energy of the X-ray photon interaction with a predetermined upper threshold value and a predetermined lower threshold value. In one embodiment, this information is communicated to computing system 530 via output signals 535 for further processing and storage.

Diffraction patterns resulting from simultaneous illumination of a periodic target with multiple illumination wavelengths are separated at the detector plane due to angular dispersion in diffraction. In these embodiments, integrating detectors are employed. The diffraction patterns are measured using area detectors, e.g., vacuum-compatible backside CCD or hybrid pixel array detectors. Angular sampling is optimized for Bragg peak integration. If pixel level model fitting is employed, angular sampling is optimized for signal information content. Sampling rates are selected to prevent saturation of zero order signals.

In a further aspect, a SXR system is employed to determine properties of a specimen (e.g., structural parameter values) based on one or more diffraction orders of scattered light. As depicted in FIG. 15, metrology tool 500 includes a computing system 530 employed to acquire signals 535 generated by detector 519 and determine properties of the specimen based at least in part on the acquired signals using an optimized geometric model as described herein.

It is desirable to perform measurements at large ranges of wavelength, angle of incidence and azimuth angle to increase the precision and accuracy of measured parameter values. This approach reduces correlations among parameters by extending the number and diversity of data sets available for analysis.

Measurements of the intensity of diffracted radiation as a function of illumination wavelength and x-ray incidence angle relative to the wafer surface normal are collected. Information contained in the multiple diffraction orders is typically unique between each model parameter under consideration. Thus, x-ray scattering yields estimation results for values of parameters of interest with small errors and reduced parameter correlation.

In one aspect, metrology tool 500 includes a wafer chuck 503 that fixedly supports wafer 501 and is coupled to specimen positioning system 540. Specimen positioning system 540 configured to actively position specimen 501 in six degrees of freedom with respect to illumination beam 514. In one example, computing system 530 communicates command signals (not shown) to specimen positioning system 540 that indicate the desired position of specimen 501. In response, specimen positioning system 540 generates command signals to the various actuators of specimen positioning system 540 to achieve the desired positioning of specimen 501.

In a further aspect, the focusing optics of an SXR system projects an image of the illumination source onto the specimen under measurement with a demagnification of at least five (i.e., magnification factor of 0.2 or less). An SXR system as described herein employs a Soft X-ray illumination source having a source area characterized by a lateral dimension of 20 micrometers or less (i.e., source size is 20 micrometers or smaller). In some embodiments, focusing optics are employed with a demagnification factor of at least five (i.e., project an image of the source onto the wafer that is five times smaller than the source size) to project illumination onto a specimen with an incident illumination spot size of four micrometers or less.

In some examples, metrology based on SXR involves determining the dimensions of the sample by the inverse solution of a pre-determined measurement model with the measured data. The measurement model includes a few (on the order of ten) adjustable parameters and is representative of the geometry and optical properties of the specimen and the optical properties of the measurement system. The method of inverse solve includes, but is not limited to, model based regression, tomography, machine learning, or any combination thereof. In this manner, target profile parameters are estimated by solving for values of a parameterized measurement model that minimize errors between the measured scattered x-ray intensities and modeled results.

Additional description of soft x-ray based metrology systems is provided in U.S. Patent Publication No. 2019/0017946, the content of which is incorporated herein by reference in its entirety.

In another further aspect, computing system 530 is configured to generate an optimized geometric model of a measured structure of a specimen as described herein, generate a SXR response model that includes at least one latent parameter from the structural model, and resolve at least one latent parameter value by performing a fitting analysis of SXR measurement data with the SXR response model. The analysis engine is used to compare the simulated SXR signals with measured data thereby allowing the determination of latent parameter values as well as material properties such as electron density of the sample. In the embodiment depicted in FIG. 15, computing system 530 is configured as a model building and analysis engine (e.g., model building and analysis engine 350) configured to implement model building and analysis functionality as described with reference to FIG. 14.

In some examples, model building and analysis engines 130 and 350 improve the accuracy of measured parameters by any combination of feed sideways analysis, feed forward analysis, and parallel analysis. Feed sideways analysis refers to taking multiple data sets on different areas of the same specimen and passing common parameters determined from the first dataset onto the second dataset for analysis. Feed forward analysis refers to taking data sets on different specimens and passing common parameters forward to subsequent analyses using a stepwise copy exact parameter feed forward approach. Parallel analysis refers to the parallel or concurrent application of a non-linear fitting methodology to multiple datasets where at least one common parameter is coupled during the fitting.

Multiple tool and structure analysis refers to a feed forward, feed sideways, or parallel analysis based on regression, a look-up table (i.e., “library” matching), or another fitting procedure of multiple datasets. Exemplary methods and systems for multiple tool and structure analysis is described in U.S. Pat. No. 7,478,019, issued on Jan. 13, 2009, to KLA-Tencor Corp., the entirety of which is incorporated herein by reference.

Although the methods discussed herein are explained with reference to systems 100, 300, and 500, any optical, x-ray, or electron beam based measurement system configured to illuminate a specimen with an amount of energy, e.g., electromagnetic radiation, electron beam energy, etc., and detect energy reflected, transmitted, or diffracted from a specimen may be employed to implement the exemplary methods described herein. Exemplary systems include an angle-resolved reflectometer, a scatterometer, a reflectometer, an ellipsometer, a spectroscopic reflectometer or ellipsometer, a beam profile reflectometer, a multi-wavelength, two-dimensional beam profile reflectometer, a multi-wavelength, two-dimensional beam profile ellipsometer, a rotating compensator spectroscopic ellipsometer, a transmissive x-ray scatterometer, a reflective x-ray scatterometer, etc. By way of non-limiting example, an ellipsometer may include a single rotating compensator, multiple rotating compensators, a rotating polarizer, a rotating analyzer, a modulating element, multiple modulating elements, or no modulating element.

It is noted that the output from a source and/or target measurement system may be configured in such a way that the measurement system uses more than one technology. In fact, an application may be configured to employ any combination of available metrology sub-systems within a single tool, or across a number of different tools.

A system implementing the methods described herein may also be configured in a number of different ways. For example, a wide range of wavelengths (including visible, ultraviolet, infrared, and X-ray), angles of incidence, states of polarization, and states of coherence may be contemplated. In another example, the system may include any of a number of different light sources (e.g., a directly coupled light source, a laser-sustained plasma light source, etc.). In another example, the system may include elements to condition light directed to or collected from the specimen (e.g., apodizers, filters, etc.).

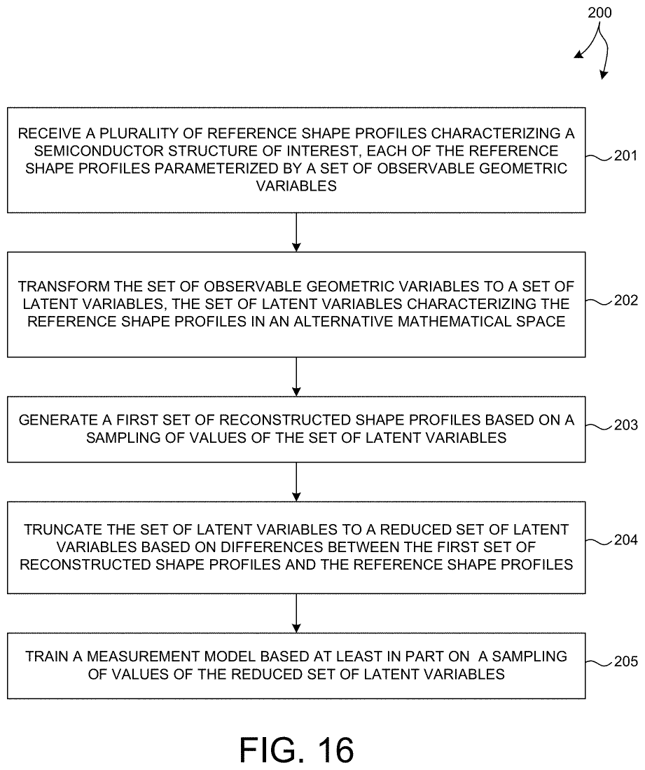

FIG. 16 illustrates a method 200 suitable for implementation by the metrology systems 100, 300, and 500 of the present invention. In one aspect, it is recognized that data processing blocks of method 200 may be carried out via a pre-programmed algorithm executed by one or more processors of computing systems 116, 330, or 530. While the following description is presented in the context of metrology systems 100, 300, and 500, it is recognized herein that the particular structural aspects of metrology systems 100, 300, and 500 do not represent limitations and should be interpreted as illustrative only.

In block 201, a plurality of reference shape profiles characterizing a semiconductor structure of interest are received, e.g., by a model building tool. Each of the reference shape profiles is parameterized by a set of observable geometric variables.

In block 202, the set of observable geometric variables is transformed to a set of latent variables. The set of latent variables characterizes the reference shape profiles in an alternative mathematical space.

In block 203, a first set of reconstructed shape profiles is generated based on a sampling of values of the set of latent variables.

In block 204, the set of latent variables is truncated to a reduced set of latent variables based on differences between the first set of reconstructed shape profiles and the reference shape profiles.

In block 205, a measurement model is trained based at least in part on a sampling of values of the reduced set of latent variables.

It should be recognized that the various steps described throughout the present disclosure may be carried out by single computer systems 116, 330, and 530, or, alternatively, multiple computer systems 116, 330, and 530. Moreover, different subsystems of systems 100, 300, and 500, such as the spectroscopic ellipsometer 101, may include a computer system suitable for carrying out at least a portion of the steps described herein. Therefore, the aforementioned description should not be interpreted as a limitation on the present invention but merely an illustration. Further, the one or more computing systems 116 may be configured to perform any other step(s) of any of the method embodiments described herein.

The computing systems 116, 330, and 530 may include, but is not limited to, a personal computer system, mainframe computer system, workstation, image computer, parallel processor, or any other device known in the art. In general, the term “computing system” may be broadly defined to encompass any device having one or more processors, which execute instructions from a memory medium. In general, computing systems 116, 330, and 530 may be integrated with a measurement system such as measurement systems 100, 300, and 500, respectively, or alternatively, may be separate from any measurement system. In this sense, computing systems 116, 330, and 530 may be remotely located and receive measurement data and user input from any measurement source and user input source, respectively.

Program instructions 120 implementing methods such as those described herein may be transmitted over or stored on carrier medium 118. The carrier medium may be a transmission medium such as a wire, cable, or wireless transmission link. The carrier medium may also include a computer-readable medium such as a read-only memory, a random access memory, a magnetic or optical disk, or a magnetic tape.

Similarly, program instructions 334 implementing methods such as those described herein may be transmitted over a transmission medium such as a wire, cable, or wireless transmission link. For example, as illustrated in FIG. 13, program instructions stored in memory 332 are transmitted to processor 331 over bus 333. Program instructions 334 are stored in a computer readable medium (e.g., memory 332). Exemplary computer-readable media include read-only memory, a random access memory, a magnetic or optical disk, or a magnetic tape.

Similarly, program instructions 534 implementing methods such as those described herein may be transmitted over a transmission medium such as a wire, cable, or wireless transmission link. For example, as illustrated in FIG. 15, program instructions stored in memory 532 are transmitted to processor 531 over bus 533. Program instructions 534 are stored in a computer readable medium (e.g., memory 532). Exemplary computer-readable media include read-only memory, a random access memory, a magnetic or optical disk, or a magnetic tape.

As described herein, the term “critical dimension” includes any critical dimension of a structure (e.g., bottom critical dimension, middle critical dimension, top critical dimension, sidewall angle, grating height, etc.), a critical dimension between any two or more structures (e.g., distance between two structures), a displacement between two or more structures (e.g., overlay displacement between overlaying grating structures, etc.), and a dispersion property value of a material used in the structure or part of the structure. Structures may include three dimensional structures, patterned structures, overlay structures, etc.

As described herein, the term “critical dimension application” or “critical dimension measurement application” includes any critical dimension measurement.

As described herein, the term “metrology system” includes any system employed at least in part to characterize a specimen in any aspect. However, such terms of art do not limit the scope of the term “metrology system” as described herein. In addition, the metrology system 100 may be configured for measurement of patterned wafers and/or unpatterned wafers. The metrology system may be configured as a LED inspection tool, edge inspection tool, backside inspection tool, macro-inspection tool, or multi-mode inspection tool (involving data from one or more platforms simultaneously), and any other metrology or inspection tool that benefits from the calibration of system parameters based on critical dimension data.

Various embodiments are described herein for a semiconductor processing system (e.g., an inspection system or a lithography system) that may be used for processing a specimen. The term “specimen” is used herein to refer to a site, or sites, on a wafer, a reticle, or any other sample that may be processed (e.g., printed or inspected for defects) by means known in the art. In some examples, the specimen includes a single site having one or more measurement targets whose simultaneous, combined measurement is treated as a single specimen measurement or reference measurement. In some other examples, the specimen is an aggregation of sites where the measurement data associated with the aggregated measurement site is a statistical aggregation of data associated with each of the multiple sites. Moreover, each of these multiple sites may include one or more measurement targets associated with a specimen or reference measurement.

As used herein, the term “wafer” generally refers to substrates formed of a semiconductor or non-semiconductor material. Examples include, but are not limited to, monocrystalline silicon, gallium arsenide, and indium phosphide. Such substrates may be commonly found and/or processed in semiconductor fabrication facilities. In some cases, a wafer may include only the substrate (i.e., bare wafer). Alternatively, a wafer may include one or more layers of different materials formed upon a substrate. One or more layers formed on a wafer may be “patterned” or “unpatterned.” For example, a wafer may include a plurality of dies having repeatable pattern features.

A “reticle” may be a reticle at any stage of a reticle fabrication process, or a completed reticle that may or may not be released for use in a semiconductor fabrication facility. A reticle, or a “mask,” is generally defined as a substantially transparent substrate having substantially opaque regions formed thereon and configured in a pattern. The substrate may include, for example, a glass material such as amorphous SiO₂. A reticle may be disposed above a resist-covered wafer during an exposure step of a lithography process such that the pattern on the reticle may be transferred to the resist.

One or more layers formed on a wafer may be patterned or unpatterned. For example, a wafer may include a plurality of dies, each having repeatable pattern features. Formation and processing of such layers of material may ultimately result in completed devices. Many different types of devices may be formed on a wafer, and the term wafer as used herein is intended to encompass a wafer on which any type of device known in the art is being fabricated.

In one or more exemplary embodiments, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a general purpose or special purpose computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

Although certain specific embodiments are described above for instructional purposes, the teachings of this patent document have general applicability and are not limited to the specific embodiments described above. Accordingly, various modifications, adaptations, and combinations of various features of the described embodiments can be practiced without departing from the scope of the invention as set forth in the claims.

What is claimed is:

1. A method comprising:
receiving a plurality of reference shape profiles characterizing a semiconductor structure of interest, each of the reference shape profiles parameterized by a set of observable geometric variables;
transforming the set of observable geometric variables to a set of latent variables, the set of latent variables characterizing the reference shape profiles in an alternative mathematical space;
generating a first set of reconstructed shape profiles based on a sampling of values of the set of latent variables;
truncating the set of latent variables to a reduced set of latent variables based on differences between the first set of reconstructed shape profiles and the reference shape profiles; and
training a measurement model based at least in part on a sampling of values of the reduced set of latent variables.

2. The method of claim 1, further comprising:
illuminating an instance of the semiconductor structure of interest with an amount of energy;
detecting an amount of measurement data associated with a measurement of the semiconductor structure of interest in response to the amount of energy;
estimating values of the reduced set of latent variables characterizing the semiconductor structure of interest based on a fitting of the trained measurement model to the amount of measurement data; and
transforming the estimated values of the reduced set of latent variables to values of the set of observable geometric variables.

3. The method of claim 1, further comprising:
generating the plurality of reference shape profiles based on a measurement of each of a plurality of instances of the structure of interest by a trusted metrology system.

4. The method of claim 1, further comprising:
generating the plurality of reference shape profiles based on a simulation of each of a plurality of instances of the structure of interest by a semiconductor fabrication process simulator.

5. The method of claim 1, wherein the plurality of reference shape profiles are user generated.

6. The method of claim 1, wherein the transforming of the set of observable geometric parameters to the values of the set of latent variables involves a principal component analysis or a trained autoencoder.

7. The method of claim 1, further comprising:
generating a second set of reconstructed shape profiles based on a sampling of values of the reduced set of latent variables;
fitting a curve to differences between the reference shape profiles and the second set of reconstructed shape profiles; and
generating a third set of reconstructed shape profiles based on a sum of the second set of reconstructed shape profiles and the fitted curve, wherein the training of the measurement model is based on the third set of reconstructed shape profiles.

8. The method of claim 1, further comprising:
extending a range of values of one or more of the set of observable variables, wherein the plurality of reference shape profiles characterizing the semiconductor structure of interest includes reference shape profiles characterized by the extended range of values.

9. The method of claim 1, further comprising:
generating a second set of reconstructed shape profiles based on a sampling of values of the reduced set of latent variables; and
eliminating non-physical shape profiles of the second set of reconstructed shape profiles.

10. A metrology system comprising:
an illumination subsystem configured to illuminate a semiconductor structure with an amount of energy at a measurement site;
a detector configured to detect an amount of measurement data associated with measurements of the semiconductor structure in response to the amount of energy; and
a computing system configured to:
estimate a value of at least one latent variable of a set of latent variables characterizing the semiconductor structure in a non-observable mathematical space based on a fitting of a trained measurement model to the amount of measurement data; and
transform the value of the at least one latent variable to a value of at least one observable geometric parameter of interest characterizing the semiconductor structure.

11. The metrology system of claim 10, the computing system further configured to:
receive a plurality of reference shape profiles characterizing the semiconductor structure, each of the reference shape profiles parameterized by a set of observable geometric variables;
transform the set of observable geometric variables to the set of latent variables, the set of latent variables characterizing the reference shape profiles in the non-observable mathematical space;
generate a first set of reconstructed shape profiles based on a sampling of values of the set of latent variables;
truncate the set of latent variables to a reduced set of latent variables based on differences between the first set of reconstructed shape profiles and the reference shape profiles; and
train the measurement model based at least in part on a sampling of values of the reduced set of latent variables.

12. The metrology system of claim 11, wherein the plurality of reference shape profiles are generated by a measurement of each of a plurality of instances of the semiconductor structure by a trusted metrology system.

13. The metrology system of claim 11, wherein the plurality of reference shape profiles are generated by a simulation of each of a plurality of instances of the structure of interest by a semiconductor fabrication process simulator.

14. The metrology system of claim 11, wherein the plurality of reference shape profiles are user generated.

15. The metrology system of claim 11, wherein the transforming of the set of observable geometric parameters to the values of the set of latent variables involves a principal component analysis or a trained autoencoder.

16. The metrology system of claim 11, the computing system further configured to:
generate a second set of reconstructed shape profiles based on a sampling of values of the reduced set of latent variables;
fit a curve to differences between the reference shape profiles and the second set of reconstructed shape profiles; and
generate a third set of reconstructed shape profiles based on a sum of the second set of reconstructed shape profiles and the fitted curve, wherein the training of the measurement model is based on the third set of reconstructed shape profiles.

17. The metrology system of claim 11, further comprising:
extending a range of values of one or more of the set of observable variables, wherein the plurality of reference shape profiles characterizing the semiconductor structure includes reference shape profiles characterized by the extended range of values.

18. The metrology system of claim 10, wherein the illumination subsystem and the detector comprise an optical metrology system, an x-ray based metrology system, or an electron beam based metrology system.

19. A metrology system comprising:
an illumination subsystem configured to illuminate a semiconductor structure with an amount of energy at a measurement site;
a detector configured to detect an amount of measurement data associated with measurements of the semiconductor structure in response to the amount of energy; and
a non-transitory, computer-readable medium storing instructions that when executed by one or more processors cause the one or more processors to:
estimate a value of at least one latent variable of a set of latent variables characterizing the semiconductor structure in a non-observable mathematical space based on a fitting of a trained measurement model to the amount of measurement data; and
transform the value of the at least one latent variable to a value of at least one observable geometric parameter of interest characterizing the semiconductor structure.

20. The metrology system of claim 19, the non-transitory, computer-readable medium further storing instructions that when executed by the one or more processors cause the one or more processors to:
receive a plurality of reference shape profiles characterizing the semiconductor structure, each of the reference shape profiles parameterized by a set of observable geometric variables;
transform the set of observable geometric variables to the set of latent variables, the set of latent variables characterizing the reference shape profiles in the non-observable mathematical space;
generate a first set of reconstructed shape profiles based on a sampling of values of the set of latent variables;
truncate the set of latent variables to a reduced set of latent variables based on differences between the first set of reconstructed shape profiles and the reference shape profiles; and
train the measurement model based at least in part on a sampling of values of the reduced set of latent variables.
